(19) United States
(12) Patent Application Publication
(10) Pub. No.: US 2009/0179241 A1
(43) Pub. Date: Jul. 16, 2009

(54) Photosensor and photo IC equipped with same

(75) Inventor: Yasuaki Kawai, Tokyo (JP)

Correspondence Address: RABIN & Berdo, PC, 1101 14TH STREET, NW, SUITE 500, WASHINGTON, DC, 20005, US

(73) Assignee: OKI SEMICONDUCTOR CO., LTD., Tokyo (JP)

(21) Appl. No.: 12/318,895

(22) Filed: Jan. 12, 2009

(30) Foreign Application Priority Data
Jan. 15, 2008 (JP) 2008-006312

(51) Int. Cl. H01L 31/08; H01L 31/09

(52) U.S. Cl. 257/292; 257/440; 257/E31.093; 257/E31.055

(57) ABSTRACT

The present invention provides a photosensor formed in a semiconductor substrate having a silicon substrate, an insulating layer formed over the silicon substrate, and a silicon semiconductor layer formed over the insulating layer, comprising an ultraviolet photosensitive element formed in the silicon semiconductor layer, and at least one visible light photosensitive element formed in the silicon substrate.

### BACKGROUND OF THE INVENTION

The present invention relates to a photosensor for detecting light in an ultraviolet region and light in a visible light region respectively, and a photo IC equipped with the photosensor.

A conventional sensor for detecting the intensity of light configures a visible light sensor wherein two visible light photosensitive elements are formed in which P-type diffusion layers are formed in surface layers of two N-type diffusion layers formed in a P-type silicon substrate, an N-type high-concentration diffusion layer is formed around one P-type diffusion layer and the difference in concentration between impurities for forming each PN junction is varied to change the depth of each depletion layer, and the intensity of light in a visible light region is detected using the difference between currents outputted from the two visible light photosensitive elements.

An ultraviolet sensor has been formed which detects the intensity of light in an ultraviolet region using the difference between output currents of two visible light photosensitive elements in which the depths of N-type diffusion layers formed in surface layers of two P-type diffusion layers formed in an N-type silicon substrate are respectively set to 500 nm and 1500 nm to change the depths of depletion layers (refer to, for example, a patent document 1 (Japanese Patent Publication Laid Open Number Hei 2(1990)-240527)).

There has been known an ultraviolet sensor that has a lateral ultraviolet photosensitive element in which an “E”-shaped N-type high-concentration diffusion layer with an N-type impurity diffused therein in a high concentration and a “π”-shaped P-type high-concentration diffusion layer with a P-type impurity diffused therein in a high concentration are placed in a silicon semiconductor layer of a semiconductor substrate of an SOI (Silicon On Insulator) structure formed with a silicon semiconductor layer having a thickness of 150 nm or so on a silicon substrate with an embedded oxide film interposed therebetween, so as to be opposite to each other in meshing engagement with each other with a silicon semiconductor layer with the N-type impurity diffused therein in a low concentration being interposed therebetween, and depletion layers are formed in a lateral direction, thereby providing exposure to only light of an ultraviolet region and that detects the intensity of light in the ultraviolet region (refer to, for example, a patent document 2 (Japanese Patent Publication Laid Open Number Hei 7(1995)-162024)).

A problem, however, arises in that since the wavelength region of light to which each photosensitive element is exposed, depends on the depth of the silicon layer formed with the depletion layer as viewed from a light-detecting surface as described in each of the patent documents 1 and 2, the thickness of the silicon semiconductor layer for forming each visible light photosensitive element that needs to form the depletion layer at the deep position falls short where the lateral ultraviolet photosensitive element is formed in the thin silicon semiconductor layer of the semiconductor substrate having the SOI structure, thus causing a difficulty in forming the ultraviolet photosensitive element and the visible light photosensitive elements in the semiconductor substrate having the SOI structure simultaneously.

Therefore, when an ultraviolet sensor equipped with an ultraviolet photosensitive element and a visible light sensor equipped with a visible light photosensitive element are provided separately and mounted to a wiring board or the like formed with a peripheral circuit thereby to form a photosensor, the manufacturing cost increases and space for providing the wiring board must be ensured for an apparatus equipped with the photosensor, thus causing a problem in that it is difficult to attain miniaturization of an apparatus equipped with a photosensor having the function of detecting light in an ultraviolet region and the function of detecting light in a visible light region.

### SUMMARY OF THE INVENTION

The present invention has been made to solve the above problems. It is therefore an object of the present invention to provide a small-sized photosensor in which an ultraviolet photosensitive element and visible light photosensitive elements are formed in a semiconductor substrate having an SOI structure to take one-chipped form.

According to one aspect of the present invention, for attaining the above object, there is provided a photosensor formed in a semiconductor substrate having a silicon substrate, an insulating layer formed over the silicon substrate, and a silicon semiconductor layer formed over the insulating layer, comprising an ultraviolet photosensitive element formed in the silicon semiconductor layer, and at least one visible light photosensitive element formed in the silicon substrate.

Thus, the present invention can bring about advantageous effects in that a photosensor having an ultraviolet detecting function and a visible light detecting function can be one-chipped and thereby brought into less size, and miniaturization of an apparatus equipped with the photosensor can be easily attained.

### BRIEF DESCRIPTION OF THE DRAWINGS

While the specification concludes with claims particularly pointing out and distinctly claiming the subject matter which is regarded as the invention, it is believed that the invention, the objects and features of the invention and further objects, features and advantages thereof will be better understood from the following description taken in connection with the accompanying drawings in which:

FIG. 1 is an explanatory diagram showing an upper surface of a photosensor according to an embodiment;

FIG. 2 is an explanatory diagram illustrating a section of the photosensor according to the embodiment;

FIG. 3 is an explanatory diagram depicting a method for manufacturing a photo IC equipped with the photosensor according to the embodiment;

FIG. 4 is an explanatory diagram depicting the operation of the photosensor according to the embodiment;

FIG. 5 is a graph showing a spectral sensitivity characteristic of a first visible light photosensitive element according to the embodiment;

FIG. 6 is a graph illustrating a spectral sensitivity characteristic of a second visible light photosensitive element according to the embodiment; and

FIG. 7 is a graph showing a spectral sensitivity characteristic in a visible light region of the photosensor according to the embodiment.

### DETAILED DESCRIPTION OF THE PREFERRED EMBODIMENTS

Preferred embodiments of a photosensor according to the present invention and a photo IC equipped therewith will hereinafter be described with reference to the accompanying drawings.

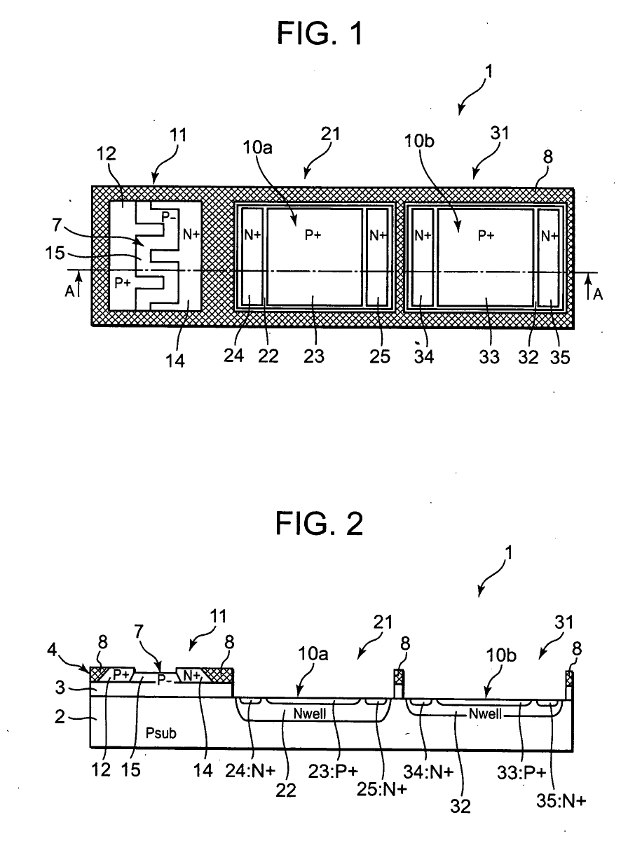

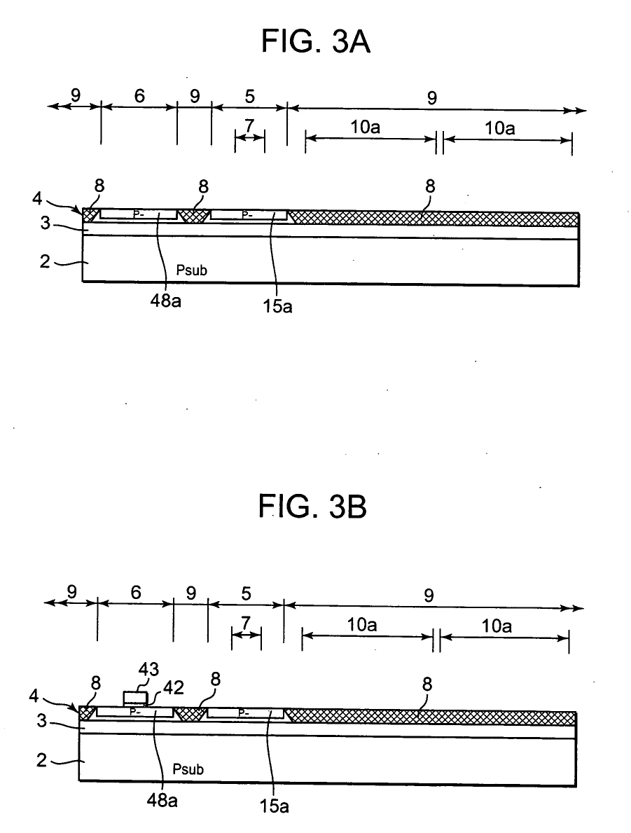

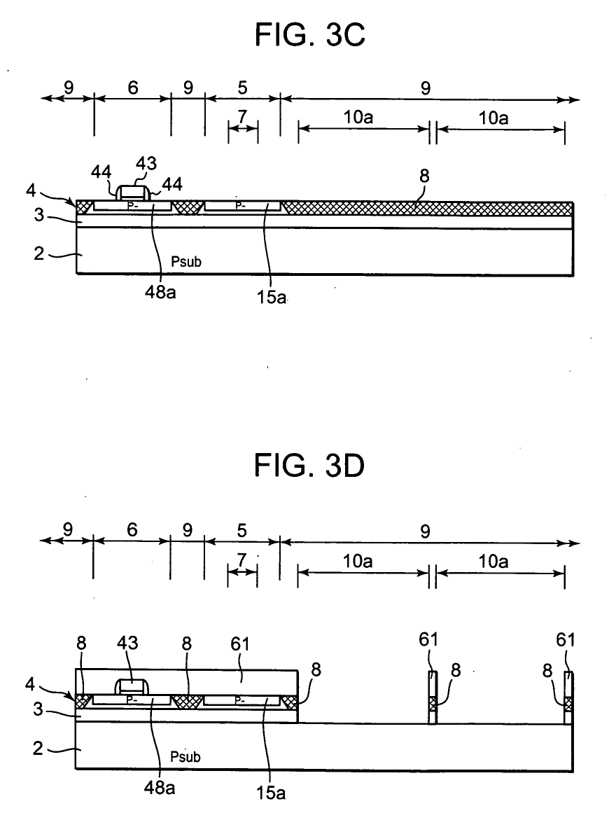

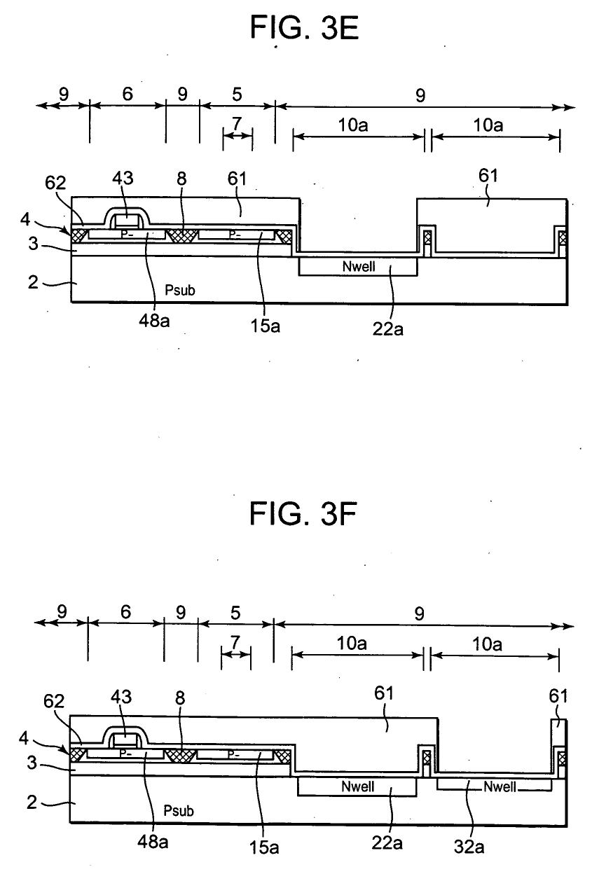

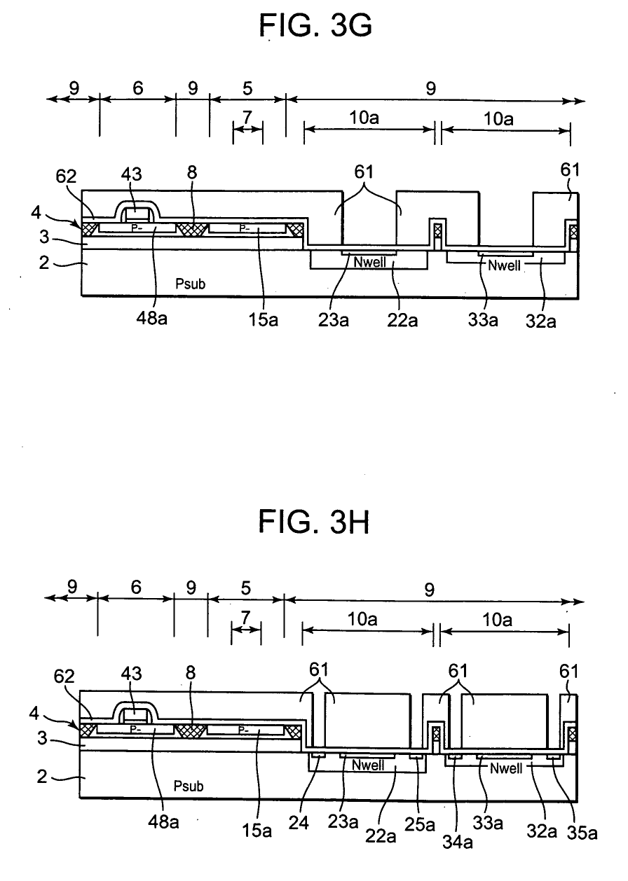

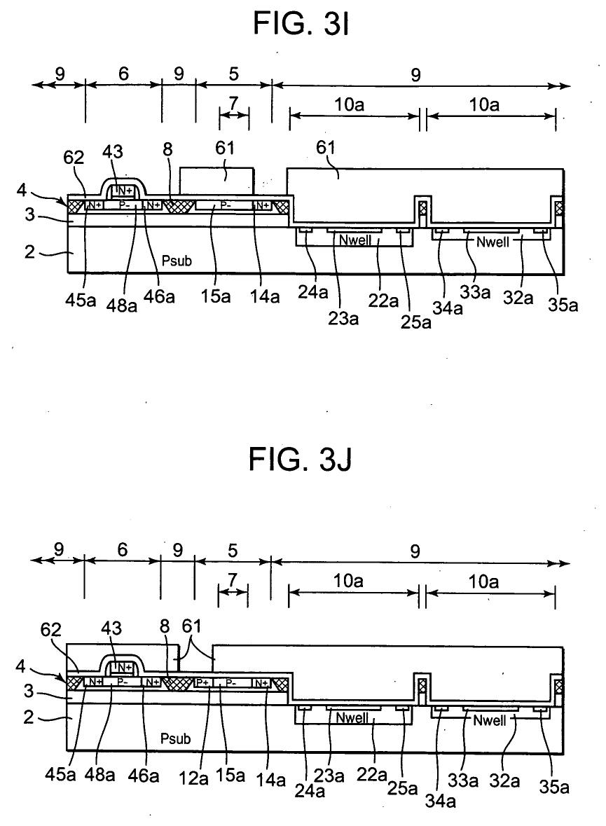

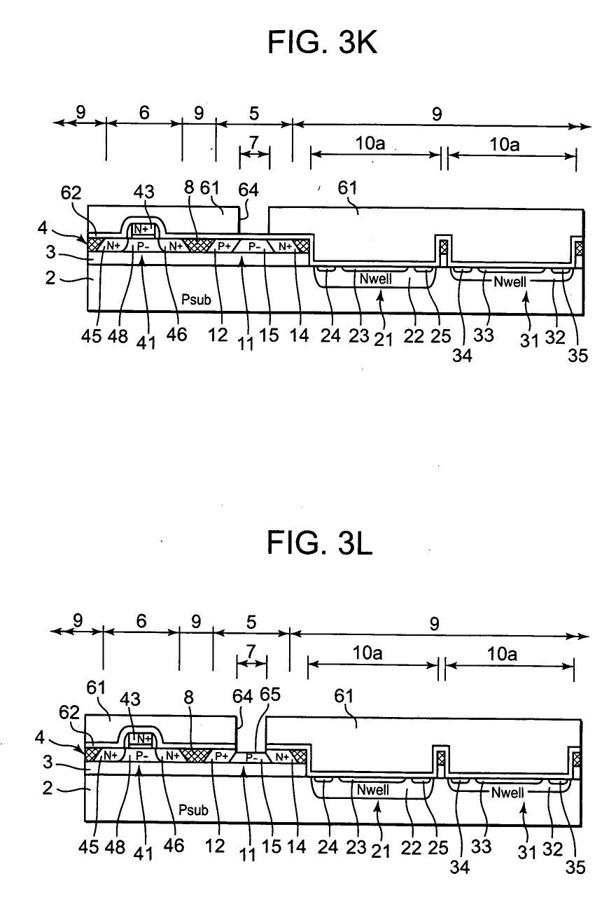

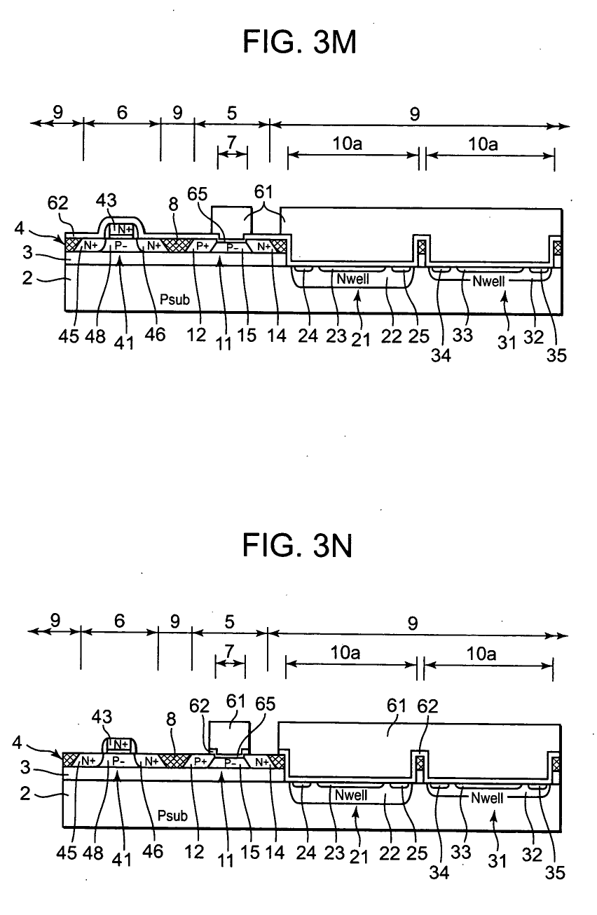

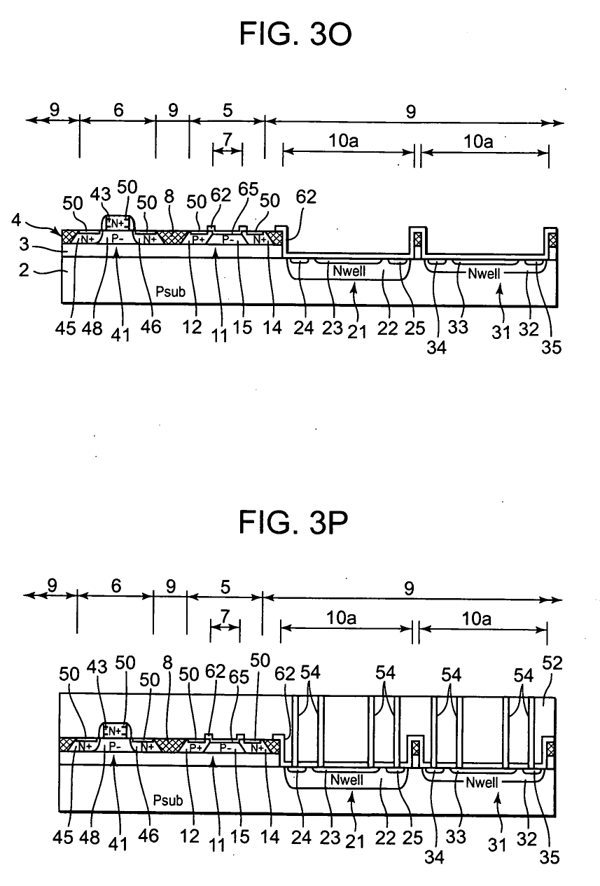

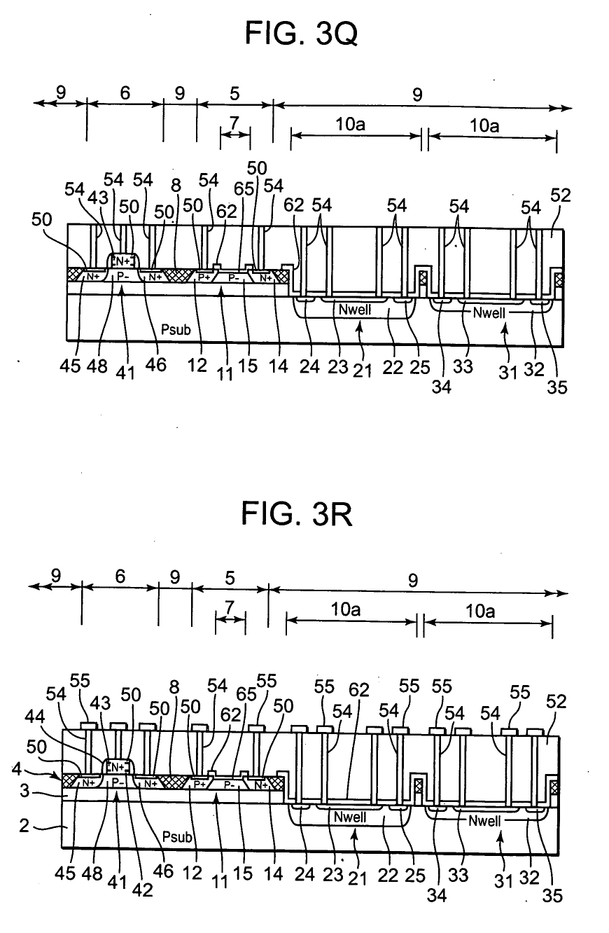

FIG. 1 is an explanatory diagram showing an upper surface of a photosensor according to an embodiment, FIG. 2 is an explanatory diagram showing a section of the photosensor according to the embodiment, and FIGS. 3A through 3R are respectively explanatory diagrams showing a method for manufacturing a photo IC equipped with the photosensor according to the embodiment.

Incidentally, FIG. 2 is a sectional view taken along line A-A of FIG. 1.

In FIGS. 1 and 2, reference numeral 1 indicates a photosensor including an ultraviolet photosensitive element 11 which is formed in a silicon semiconductor layer 4 of a semiconductor substrate having an SOI structure in which the silicon semiconductor layer 4 comprised of thin monocrystal silicon is formed on a silicon substrate 2 comprised of silicon (Si) with an embedded oxide film 3 used as an insulating layer comprising silicon oxide (SiO₂) being interposed therebetween, and first and second visible light photosensitive elements 21 and 31 formed therein.

As shown in FIGS. 3A through 3R, an ultraviolet element forming area 5 for forming the ultraviolet photosensitive element 11 of the photosensor 1, and a plurality of transistor forming areas 6 for forming nMOS elements 41 and unillustrated pMOS elements each used as a MOSFET (Metal Oxide Semiconductor Field Effect Transistor) that configures a peripheral circuit, are set to the silicon semiconductor layer 4 of the present embodiment. A film-thinning area 7 is set to the ultraviolet element forming area 5 as a region or area for forming the silicon semiconductor layer 4 thinner than the silicon semiconductor layer 4 of each transistor forming area 6.

A device or element isolation area 9 for forming a device or element isolation layer 8 in areas that surround the peripheries of the ultraviolet element forming area 5 and the transistor forming areas 6 is set to the silicon semiconductor layer 4. A first visible light element forming area 10a for forming the first visible light photosensitive element 21 and a second visible light element forming area 10b for forming the second visible light photosensitive element 31 are set to the silicon substrate 2 of the element isolation area 9.

The silicon substrate 2 employed in the present embodiment is formed as a silicon substrate of a P type (hereinafter called “P-type silicon substrate 2”) by diffusing a P-type impurity such as boron (B) or boron difluoride (BF₂) corresponding to a first conductivity-type impurity employed in the present embodiment in a relatively low concentration in advance.

The element isolation layer 8 is formed in the silicon semiconductor layer 4 for the element isolation area 9 by an insulating material such as silicon oxide so as to reach the embedded oxide film 3 and has the function of electrically insulating and separating between the ultraviolet element forming area 5 and the transistor forming areas 6 adjacent to one another.

Incidentally, the element isolation layer 8 is shown with being hatched for distinction as shown in FIG. 1, FIG. 2 and the like in the present description.

The ultraviolet photosensitive element 11 of the present embodiment is formed in the ultraviolet element forming area 5 set to the silicon semiconductor layer 4.

Reference numeral 12 indicates a P-type high-concentration diffusion layer (first diffusion layer), which is of a diffusion layer formed by diffusing a P-type impurity into the silicon semiconductor layer 4 in the ultraviolet element forming area 5 in a relatively high concentration. As shown in FIG. 1, the P-type high-concentration diffusion layer 12 is formed of a peak portion that contacts one inner side of the element isolation layer 8, and a plurality of comb-tooth portions that extend toward the other side opposite to the one side as viewed from the peak portion.

The P-type high-concentration diffusion layer 12 of the present embodiment is formed in a “π”-like comb-shaped fashion by causing the two comb-tooth portions to extend from the peak portion.

Reference numeral 14 indicates an N-type high-concentration diffusion layer (second diffusion layer), which is of a diffusion layer formed by diffusing an N-type impurity such as phosphorus (P) or arsenic (As) corresponding to a second conductivity-type impurity of the present embodiment being a type opposite to the first conductivity-type impurity, into the silicon semiconductor layer 4 in the ultraviolet element forming area 5 in a relatively high concentration. As shown in FIG. 1, the N-type high-concentration diffusion layer 14 is formed of a peak portion that contacts the other inner side of the element isolation layer 8, and a plurality of comb-tooth portions that extend toward one side opposite thereto as viewed from the peak portion.

The N-type high-concentration diffusion layer 14 of the present embodiment is formed in an “E”-like comb-shaped fashion by causing the three comb-tooth portions to extend from both ends of the peak portion and its central portion.

Reference numeral 15 indicates a P-type low-concentration diffusion layer (third diffusion layer) used as a low-concentration diffusion layer, which is of a diffusion layer formed by diffusing, in a relatively low concentration, a P-type impurity into the silicon semiconductor layer 4 made thin in thickness, which contacts the P-type high-concentration diffusion layer 12 and the N-type high-concentration diffusion layer 14 spaced away from each other and disposed opposite to each other with their comb-tooth portions being engaged. When light is applied onto a plane-direction depletion layer taken along the upper surface of the silicon semiconductor layer 4 formed herein, the P-type low-concentration diffusion layer 15 mainly absorbs ultraviolet rays and thereby generates electron-positive hole pairs.

In order to form the silicon semiconductor layer 4 made thin in thickness, an area or region for forming the P-type low-concentration diffusion layer 15 interposed between the “π”-shaped P-type high-concentration diffusion layer 12 and the “E”-shaped N-type high-concentration diffusion layer 14 in the ultraviolet element forming area 5 shown in FIG. 1 is set as the film-thinning area 7.

The first visible light photosensitive element 21 of the present embodiment is formed in the corresponding first visible light element forming area 10a set to the P-type silicon substrate 2 of the element isolation area 9.

Reference numeral 22 indicates a first N-well layer used as a first well layer, which is formed by diffusing, in a relatively low concentration, an N-type impurity into substantially the whole region of the P-type silicon substrate 2 exposed by eliminating by etching, the element isolation layer 8 and the embedded oxide film 3 in the first visible light element forming area 10a formed in the semiconductor substrate. The first N-well layer 22 is of a diffusion layer relatively deep in depth as viewed from the upper surface (light-detecting surface of the P-type silicon substrate 2 and is formed to a depth of 2500 nm or so in the present embodiment.

Reference numeral 23 indicates a first P+ diffusion layer used as a first first conductivity-type diffusion layer, which is of a diffusion layer formed by diffusing a P-type impurity into a surface layer at the central part of the first N-well layer 22 in a relatively high concentration. The first P+ diffusion layer 23 is formed to a depth of 500 nm or so as viewed from the light-detecting surface.

When light transmitted through the first P+ diffusion layer 23 from the light-detecting surface is applied to a relatively deep depletion layer formed on the first N-well layer 22 side at a boundary face between the bottom face of the first P+ diffusion layer 23 and the first N-well layer 22, the first P+ diffusion layer 23 mainly absorbs visible light and ultraviolet rays and thereby generates electron-positive hole pairs.

Reference numerals 24 and 25 indicate first N+ diffusion layers each used as a first second conductivity-type diffusion layer, which are of diffusion layers formed by diffusing an N-type impurity into both sides of the first P+ diffusion layer 23 formed in the central part of the first N-well layer 22 in a relatively high concentration. They are respectively formed at positions spaced away from the first P+ diffusion layer 23.

The second visible light photosensitive element 31 of the present embodiment is formed in its corresponding second visible light element forming area 10b set to the P-type silicon substrate 2 of the element isolation area 9.

Reference numeral 32 indicates a second N-well layer used as a second well layer, which is of a diffusion layer relatively shallow in depth as viewed from the light-detecting surface of the p-type silicon substrate 2, which diffusion layer being formed by diffusing, in a relatively low concentration, an N-type impurity into substantially the whole region of the P-type silicon substrate 2 exposed by eliminating by etching, the element isolation layer 8 and the embedded oxide film 3 of the second visible light element forming area 10b formed in the semiconductor substrate. The second N-well layer 32 is formed to a depth of 1000 nm or so in the present embodiment.

Reference numeral 33 indicates a second P+ diffusion layer used as a second first conductivity-type diffusion layer, which is of a diffusion layer formed by diffusing a P-type impurity into a surface layer at the central part of the second N-well layer 32 in a relatively high concentration. The second P+ diffusion layer 33 is formed to a depth of 200 nm or so as viewed from the light-detecting surface.

When light transmitted through the second P+ diffusion layer 33 from the light-detecting surface is applied to a relatively shallow depletion layer formed on the second N-well layer 32 side at a boundary face between the bottom face of the second P+ diffusion layer 33 and the second N-well layer 32, the second P+ diffusion layer 33 mainly absorbs visible light and thereby generates electron-positive hole pairs.

Reference numerals 34 and 35 indicate second N+ diffusion layers each used as a second second conductivity-type diffusion layer, which are of diffusion layers formed by diffusing an N-type impurity into both sides of the second P+ diffusion layer 33 formed in the central part of the second N-well layer 32 in a relatively high concentration. They are respectively formed at positions spaced away from the second P+ diffusion layer 33.

The ultraviolet photosensitive element 11 and the first and second visible light photosensitive elements 21 and 31 according to the present embodiment are formed together with the nMOS element 41 and the unillustrated pMOS element or the like that configure the peripheral circuit for controlling the ultraviolet photosensitive element 11 and the first and second visible light photosensitive elements 21 and 31 as shown in FIG. 3R or the like. The corresponding photo IC equipped with the photosensor 1 is formed.

The nMOS element 41 of the present embodiment is formed in its corresponding transistor forming area 6 set to the silicon semiconductor layer 4.

In FIG. 3R, reference numeral 42 indicates a gate oxide film, which is of an insulating film relatively thin in thickness comprised of an insulating material such as silicon oxide.

Reference numeral 43 indicates a gate electrode, which is of an electrode composed of polysilicon or the like, in which an impurity (N type corresponding to second conductivity-type impurity in the present embodiment) of the same type as a source layer 45 (to be described later) is diffused in a relatively high concentration. The gate electrode 43 is formed opposite to the silicon semiconductor layer 4 of the transistor forming area 6 at the central part as viewed in a gate-length direction, of the transistor forming area 6 with the gate oxide film 42 interposed therebetween. Sidewalls 44 each comprised of an insulating material such as silicon oxide are formed at side faces of the gate electrode 43.

The source layer 45 and a drain layer 46 in which an N-type impurity is diffused in a relatively high concentration, are formed in the silicon semiconductor layer 4 on both sides of the gate electrode 43 in the transistor forming area 6.

The P-type silicon semiconductor layer 4 lying in the midst of the silicon semiconductor layer 4 in which the P-type impurity located below the gate oxide film 42 is diffused in a relatively low concentration, functions as a channel region 48 in which a channel for the nMOS element 41 of the present embodiment is formed.

Incidentally, the pMOS element is similarly formed in another transistor forming area 6 set to the silicon semiconductor layer 4 with the conductivity type of the impurity of the nMOS element 41 being set in reverse.

The gate-length direction indicates a direction extending from the source layer 45 to the drain layer 46 in parallel with the upper surface of the silicon semiconductor layer 4 or its reverse direction.

Reference numerals 50 indicate silicide layers, each of which is of a layer having conductivity, comprising a silicon compound formed by combining a silicidation material such as cobalt (Co), titanium (Ti) or the like with silicon by an annealing process. The silicide layers 50 are formed above the gage electrode 43 of the nMOS element 41, above the source layer 45 and the drain layer 46 and above the P-type high-concentration diffusion layer 12 and N-type high-concentration diffusion layer 14 of the ultraviolet photosensitive element 11.

Reference numeral 52 indicates an interlayer insulating film, which is of an insulating film relatively thick in thickness, comprised of an insulating material having a light-transmissive property, such as NSG (Nondoped Silica Glass) or silicon oxide that covers the ultraviolet photosensitive element 11 and the nMOS element 41 or the like formed on the semiconductor layer 4, and the first and second visible light photosensitive elements 21 and 31 formed in the P-type silicon substrate 2.

Reference numerals 54 indicate contact plugs, which are of conductive plugs formed by embedding a conductive material such as tungsten (W) or aluminium (Al) into contact holes opened as through holes that extend through the interlayer insulating film 52 and reach the silicide layers 50 of the source layer 45 and drain layer 46 of the nMOS element 41, the P-type high-concentration diffusion layer 12 and N-type high-concentration diffusion layer 14 of the ultraviolet photosensitive element 11, and the first and second P+ diffusion layers 22 and 23 and first and second N+ diffusion layers 24, 25, 34 and 35 of the first and second visible light photosensitive elements 21 and 31. The contact plugs 54 are electrically connected to wirings 55 formed on the interlayer insulating film 52 with a conductive material similar to the contact plugs 54.

In FIG. 3, reference numeral 61 indicates a resist mask used as a mask member, which is a mask pattern formed by performing exposure and development processing on a positive or negative resist applied onto the silicon semiconductor layer 4 by photolithography. The resist mask 61 functions as a mask for etching and ion implantation according to the present embodiment.

The thickness of the silicon semiconductor layer 4 thin in thickness in the film-thinning area 7 in the present embodiment is formed to a thickness that ranges from 3 nm or more to 36 nm or less, which has been proposed in Japanese Patent Application No. 2007-311089 or the like by the applicant (30 nm in the present embodiment).

This is because if the thickness of the silicon semiconductor layer 4 is set to such a thickness, then the corresponding ultraviolet photosensitive element 11 having peak sensitivity contained in a wavelength lying in an ultraviolet region can be formed.

The thickness of the silicon semiconductor layer 4 is formed to a thickness (50 nm in the present embodiment) ranging from 40 nm or more to 100 nm or less to ensure the operation of each MOSFET such as the nMOS element 41.

A method for manufacturing the photo IC equipped with the photosensor according to the present embodiment will be explained below in accordance with processes indicated P in FIGS. 3A through 3R.

A semiconductor substrate employed in the present embodiment is of a substrate obtained by forming, by a thermal oxidation method, a sacrifice oxide film in a silicon layer of a semiconductor substrate of an SOI structure formed with the silicon layer being left on the embedded oxide film 3 by a SIMOX (Separation by Implanted Oxygen), or a semiconductor substrate of an SOI structure in which a silicon layer is laminated on the embedded oxide film 3 and eliminating it by wet etching thereby to form the thickness of the silicon semiconductor layer 4 to 50 nm.

In FIG. 3A, a semiconductor substrate in which a silicon semiconductor layer 4 whose thickness is set to 50 nm is formed on its corresponding embedded oxide film 3 formed on a P-type silicon substrate 2, is prepared. A pad oxide film thin in thickness is formed on the silicon semiconductor layer 4 by the thermal oxidation method. A silicon nitride film comprised of silicon nitride (Si₃N₄) is formed on the pad oxide film by a CVD (Chemical Vapor Deposition) method. A resist mask 61 (not shown) that exposes an element isolation area 9 by photolithography is formed on the silicon nitride film. With the resist mask 61 as a mask, the silicon nitride film is eliminated by anisotropic etching to expose the pad oxide film.

The resist mask 61 is eliminated and the silicon semiconductor layer 4 of the element isolation area 9 is oxidized by a LOCOS (Local Oxidation Of Silicon) method with the exposed silicon nitride film as a mask to form an element isolation layer 8 that reaches the embedded oxide film 3. The silicon nitride film and the pad oxide film are removed by wet etching to form the corresponding element isolation layer 8 in the element isolation area 9 of the silicon semiconductor layer 4.

A resist mask 61 that has exposed an ultraviolet element forming area 5 and a transistor forming area 7 in the silicon semiconductor layer 4, i.e., that covers the transistor forming area 6 for forming an unillustrated pMOS element is formed on the silicon semiconductor layer 4 by photolithography. P-type low-concentration implant layers 15a and 48a are formed which are obtained by, with the resist mask 61 as a mask, implanting P-type impurity ions into the silicon semiconductor layers 4 in the exposed ultraviolet element forming area 5 and transistor forming area 6 and implanting a P-type impurity into the silicon semiconductor layers 4 in a relatively low concentration. Then, the resist mask 61 is removed.

In FIG. 3B, the upper surface of the silicon semiconductor layer 4 is oxidized by the thermal oxidation method to form a silicon oxide film comprised of silicon oxide. Polysilicon is deposited on the silicon oxide film by the CVD method to form a relatively thick polysilicon layer. A resist mask 61 (not shown) that covers a region for forming a gate electrode 43 at a central portion in a gate-length direction, of the corresponding transistor forming area 6 is formed on the polysilicon layer by photolithography. The polysilicon layer and the silicon oxide film are etched by anisotropic etching with the resist mask as a mask to expose the corresponding silicon semiconductor layer 4, thereby forming the corresponding gate electrode 43 opposite to the silicon semiconductor layer 4 via the gate oxide film 42, followed by removal of the resist mask 61.

In FIG. 3C, silicon oxide is then deposited over the entire surface of the silicon semiconductor layer 4 for the gate electrode 43 or the like by the CVD method to form a silicon oxide film. The silicon oxide film is etched by anisotropic etching to expose the upper surface of the gate electrode 43 and the upper surface of the silicon semiconductor layer 4, followed by formation of sidewalls 44 on the side faces of the gate electrode 43.

In FIG. 3D, a resist mask 61 having exposed the element isolation layer 8 of each of first and second visible light element forming areas 10a and 10b is formed on the silicon semiconductor layer 4 by photolithography. With the resist mask 61 as a mask, the exposed element isolation layer 8 and embedded oxide film 3 are etched by anisotropic etching to expose the P-type silicon substrate 2 in the first and second visible light element forming areas 10a and 10b.

In FIG. 3E, the resist mask 61 formed in the process P4 is eliminated and NSG is deposited on the silicon semiconductor layer 4 for the gate electrode 43 or the like and over the entire surface of the exposed P-type silicon substrate 2 or the like by the CVD method to form an NSG layer 62 used as an insulating material layer to a predetermined thickness (10 nm in the present embodiment). A resist mask 61 having exposed the NSG layer 62 lying on the P-type silicon substrate 2 in the forming region of the first N-well layer 22 in the first visible light element forming area 10a is formed on the NSG layer 62 by photolithography. With the resist mask 61 as a mask, N-type impurity (phosphorus in the present embodiment) ions are implanted on an implantation condition of an implantation energy of 2 MeV and a dose of 1×10¹³/cm² thereby to form a first N-well implant layer 22a obtained by implanting the N-type impurity in the first visible light element forming area 10a of the P-type silicon substrate 2 relatively deep in a low concentration.

In FIG. 3F, the resist mask 61 formed in the process P5 is removed and a resist mask 61 having exposed the NSG layer 62 lying on the P-type silicon substrate 2 in the corresponding forming region of the second N-well layer 32 of the second visible light element forming area 10b is formed on the NSG layer 62 by photolithography. With the resist mask 61 as a mask, the N-type impurity (phosphorus in the present embodiment) ions are implanted on an implantation condition of an implantation energy of 500 KeV and a dose of 3×10¹²/cm² thereby to form a second N-well implant layer 32a obtained by implanting the N-type impurity in the second visible light element forming area 10b of the P-type silicon substrate 2 relatively shallowly in a low concentration.

In FIG. 3G, the resist mask 61 formed in the process P6 is eliminated and a resist mask 61 having exposed the NSG layer 62 lying on the P-type silicon substrate 2 in each of the corresponding forming regions of the first and second P+ diffusion layers 23 and 33 at the central parts of the first and second N-well implant layers 22a and 32a is formed on the NSG layer 62 by photolithography. With the resist mask 61 as a mask, P-type impurity (boron difluoride in the present embodiment) ions are implanted on an implantation condition of an implantation energy of 40 KeV and a dose of 5×10¹⁵/cm² thereby to form P-type high-concentration implant layers 23a and 33a obtained by implanting the P-type impurity in the surface layers of the first and second N-well implant layers 22a and 32a in a relatively high concentration.

In FIG. 3H, the resist mask 61 formed in the process P7 is removed and a resist mask 61 having exposed the NSG layer 62 lying on the P-type silicon substrate 2 in each of the corresponding forming regions of the first and second N+ diffusion layers 24, 25, 34 and 35 lying on both sides of the P-type high-concentration implant layers 23a and 33a of the first and second N-well implant layers 22a and 32a is formed on the NSG layer by photolithography. With the resist mask 61 as a mask, the N-type impurity (phosphorus in the present embodiment) ions are implanted continuously at two stages of an implantation condition of an implantation energy of 300 KeV and a dose of 5×10¹²/cm² and an implantation condition of an implantation energy of an implantation energy of 60 KeV and a dose of 5×10¹⁵/cm² thereby to form N-type high-concentration implant layers 24a, 25a, 34a and 35a obtained by implanting the N-type impurity in the surface layers lying on both sides of the P-type high-concentration implant layers 23a and 33a of the first and second N-well implant layers 22a and 32a in a relatively high concentration.

The ion implantation of the two stages makes it possible to uniformize in-depth concentration profiles of impurity at the N-type high-concentration implant layers 24a, 25a, 34a and 35a and prevent the formation of an unexpected PN junction due to the P-type impurity being left on the upper surface side of each implant layer.

In FIG. 3I, the resist mask 61 formed in the process P8 is removed and a resist mask 61 having exposed the corresponding area or region (“E”-shaped portion shown in FIG. 1) for forming the N-type high-concentration diffusion layer 14 of the ultraviolet element forming area 5 and the NSG layer 62 lying on the silicon semiconductor layer 4 of the transistor forming area 6 is formed by photolithography. With the resist mask 61 as a mask, N-type impurity ions are implanted into the silicon semiconductor layer 4 and polysilicon of the gate electrode 43 thereby to form N-type high-concentration implant layers 14a, 45a and 46a obtained by implanting the N-type impurity into the gate electrode 43 in a high concentration and implanting, in a high concentration, the N-type impurity into the silicon semiconductor layer 4 in each of regions for forming the source layer 45 and drain layer 46 lying on both sides of the sidewalls 44, and the silicon semiconductor layer 4 in a region for forming the N-type high-concentration diffusion layer 14.

In FIG. 3J, the resist mask 61 formed in the process P9 is removed and a resist mask 61 having exposed the NSG layer 62 lying on the silicon semiconductor layer 4 in the corresponding region (“π”-shaped portion shown in FIG. 1) for forming the P-type high-concentration diffusion layer 12 of the ultraviolet element forming area 5 is formed by photolithography. With the resist mask 61 as a mask, P-type impurity ions are implanted in the silicon semiconductor layer 4 thereby to form a P-type high-concentration implant layer 12a obtained by implanting a P-type impurity into the silicon semiconductor layer 4 in the corresponding region for forming the P-type high-concentration diffusion layer 12 in a high concentration.

In FIG. 3K, the resist mask 61 formed in the process P10 is eliminated. The impurities implanted into the respective implant layers are activated by heat treatment at a high temperature to diffuse an impurity of a predetermined type into the respective diffusion layers in a predetermined concentration, thereby forming a P-type high-concentration diffusion layer 12, an N-type high-concentration diffusion layer 14 and a P-type low-concentration diffusion layer 15 for an ultraviolet photosensitive element 11 in the ultraviolet element forming area 5, forming a first N-well layer 22 of the first visible light photosensitive element 21, having a depth of 2500 nm or so, a first P+ diffusion layer 23 thereof having a depth of 500 nm and first N+ diffusion layers 24 and 25 thereof each having the depth of 500 nm, in the first visible light element forming area 10a, forming a second N-well layer 32 of the second visible light photosensitive element 31, having a depth of 1000 nm, a second P+ diffusion layer 33 thereof having a depth of 200 nm or so and second N+ diffusion layers 34 and 35 thereof each having the depth of 200 nm or so in the second visible light element forming area 10b, and forming source and drain layers 45 and 46 of an nMOS element 41 in the transistor forming area 6.

After the heat treatment, a resist mask 61 having an opening 64 having exposed the NSG layer 62 lying on the silicon semiconductor layer 4 in the thin-forming area 7 is formed on the corresponding NSG layer 62 by photolithography.

In FIG. 3L, the exposed NSG layer 62 and silicon semiconductor layer 4 are etched by anisotropic etching with the resist mask 61 formed in the process P11 as a mask to form a concave or recess portion 65 for thinning the thickness of the silicon semiconductor layer 4 to a predetermined thickness (30 nm in the present embodiment) set to the film-thinning area 7, thereby thinning the thickness of a P-type low-concentration diffusion layer 15 to a predetermined thickness.

In FIG. 3M, the resist mask 61 formed in the process P11 is removed and the remaining NSG layer 62 is held as it is. NSG is deposited over the entire surface of the NSG layer 62 or the like lying on the gate electrode 43, the concave portion 65, the silicon semiconductor layer 4 and the P-type silicon substrate 2 by the CVD method to increase the thickness of the NSG layer 62. A resist mask 61 that covers the NSG layer 62 for the film-thinning area 7 and its periphery, and the first and second visible light element forming areas 10a and 10b and their peripheries, i.e., that has exposed the P-type high-concentration diffusion layer 12, the N-type high-concentration diffusion layer 14, the source and drain layers 45 and 46 of the nMOS element 41, and the silicon semiconductor layer 4 and polysilicon in their corresponding silicide layer forming area lying on the gate electrode 43 is formed on the thickness-increased NSG layer 62 by photolithography.

In FIG. 3N, the exposed NSG layer 62 is etched by anisotropic etching for selectively etching NSG with the resist mask 61 formed in the process P13 as a mask to expose the silicon semiconductor layer 4 and polysilicon of the gate electrode 43.

In FIG. 30, the resist mask 61 formed in the process P13 is removed. A silicidation material layer composed of a silicidation material (cobalt in the present embodiment) is formed on the gate electrode 43 and over the entire surfaces of the remaining NSG layer 62 and element isolation layer 8 or the like on the silicon semiconductor layer 4 by a sputtering method. The silicon semiconductor layer 4 for the P-type high-concentration diffusion layer 12, N-type high-concentration diffusion layer 14 and the source and drain layers 45 and 46 of the nMOS element 41, and the polysilicon of the gate electrode 43 are silicidized by a salicide process including RTA (Rapid Thermal Anneal) to form silicide layers 50 in the respective diffusion layers. The salicide process in this case means a process from the execution of RTA to the removal of the unreacted silicidation material layer.

In this case, the remaining NSG layer 62 and element isolation layer 8 function as masks for preventing the reaction of the silicidation material and silicon.

In FIG. 3P, the remaining NSG layer 62 is held as it is after the salicide process. NSG is deposited relatively thick on the entire upper surfaces of the silicon semiconductor layer 4 and P-type silicon substrate 2 by the CVD method. The upper surface thereof is planarized to form an interlayer insulating film 52. A resist mask 61 (not shown) having openings having exposed the interlayer insulating film 52 lying in forming regions of the contact plugs 54 on the first and second P+ diffusion layers 23 and 33 and first and second N+ diffusion layers 24, 25, 34 and 35 of the first and second visible light photosensitive elements 21 and 31 is formed on the interlayer insulating film 52 by photolithography. Contact holes that extend through the interlayer insulating film 52 and reach the respective diffusion layers are formed by anisotropic etching for selectively etching NSG with the resist mask 61 as a mask. After the removal of the resist mask 61, a conductive material is embedded into the contact holes by the CVD method or sputtering method to form their corresponding contact plugs 54. Their upper surfaces are planarized to expose the upper surface of the interlayer insulating film 52.

In FIG. 3Q, a resist mask 61 (not shown) having openings having exposed the interlayer insulating film 52 in the forming regions of the contact plugs 54 on the P-type high-concentration diffusion layer 12 and N-type high-concentration diffusion layer 14 of the ultraviolet photosensitive element 11 and the source and drain layers 45 and 46 of the nMOS element 41 is formed on the interlayer insulating film 52 by photolithography. In a manner similar to the process P15, contact holes that reach the silicide layers 50 on the respective diffusion layers are formed. After the removal of the resist mask 61, contact plugs 54 are formed in a manner similar to the process P15. After their planarization or flattering process, a contact plug 54 that reaches the silicide layer 50 of the gate electrode 43 is formed in a manner similar to the above. It is subjected to the flattering process to expose the upper surface of the interlayer insulating film 52.

In FIG. 3R, a wiring layer composed of a conductive material is formed on the interlayer insulating film 52 by the CVD method or the sputtering method. A resist mask 61 (not shown) that covers regions for forming wirings 55 is formed on the wiring layer by photolithography. With the resist mask 61 as a mask, the wiring layer is etched to expose the interlayer insulating film 52. The resist mask 61 is removed to form the wirings 55 electrically connected to the contact plugs 54 respectively.

A one-chipped photosensor 1 equipped with the ultraviolet photosensitive element 11 and the first and second visible light photosensitive elements 21 and 31 employed in the present embodiment is formed in this way. A photo IC equipped with the nMOS element 41 and the like that constitute the peripheral circuit for controlling those is formed.

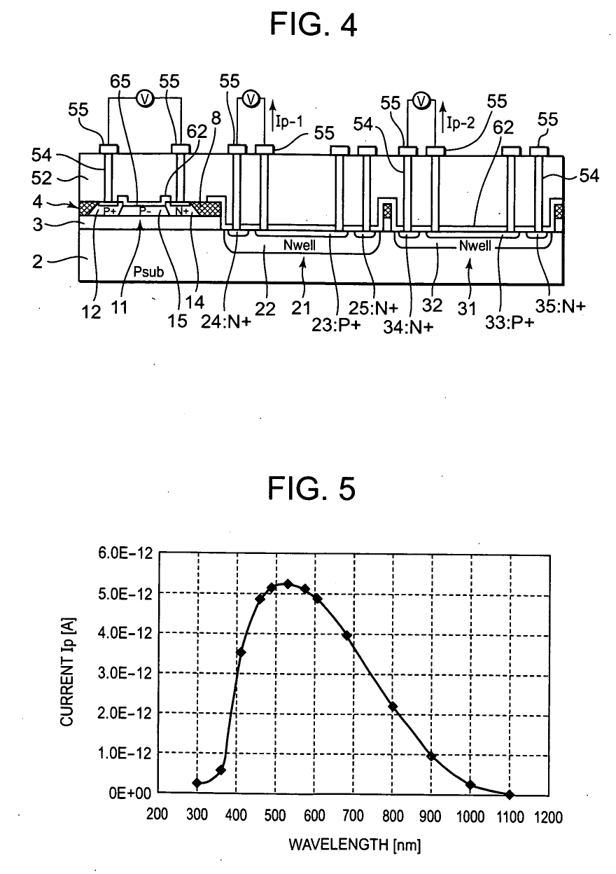

Consider where the intensity of light in an ultraviolet region (400 nm or less in wavelength) and the intensity of light in a visible light region (400 nm to 800 nm in wavelength) are detected using the photosensor 1. When the voltage is applied between the N-type high-concentration diffusion layer 14 and the P-type high-concentration diffusion layer 12 of the ultraviolet photosensitive element 11, which are formed in the silicon semiconductor layer 4 as shown in FIG. 4 in this case, a thin depletion layer in a plane direction is formed in the P-type low-concentration diffusion layer 15. When light transmitted through the interlayer insulating film 52 and the NSG layer 62 formed of an insulating material such as NSG having a light-transmissive property or translucency is applied onto the depletion layer, a visible light region is cut by the thickness of the P-type low-concentration diffusion layer 15, so that light in the ultraviolet region is absorbed so that electron-positive pairs are generated, which in turn are pull out as current from the P-type high-concentration diffusion layer 12, whereby the intensity of light in the ultraviolet region is detected.

On the other hand, when the voltage is applied between the first P+ diffusion layer 23 and the first N+ diffusion layer 24 of the first visible light photosensitive element 21, which are formed in the P-type silicon substrate 2, a depletion layer deep as viewed from the bottom face of the first P+ diffusion layer 23 is formed in the first N-well layer 22 formed deep relatively. When light transmitted through the interlayer insulating film 52, NSG layer 62 and first P+ diffusion layer 23 is applied to the deep depletion layer, visible light and light in an infrared region are absorbed so that electron-positive hole pairs are generated. This is pulled out as a current Ip-1 from the first P+ diffusion layer 23. When the voltage to be applied is assumed to be 1V and light having a wavelength ranging from 300 nm to 1000 nm is applied, a spectral sensitivity characteristic with a wavelength of 550 nm as a peak, which is shown in FIG. 5, is obtained.

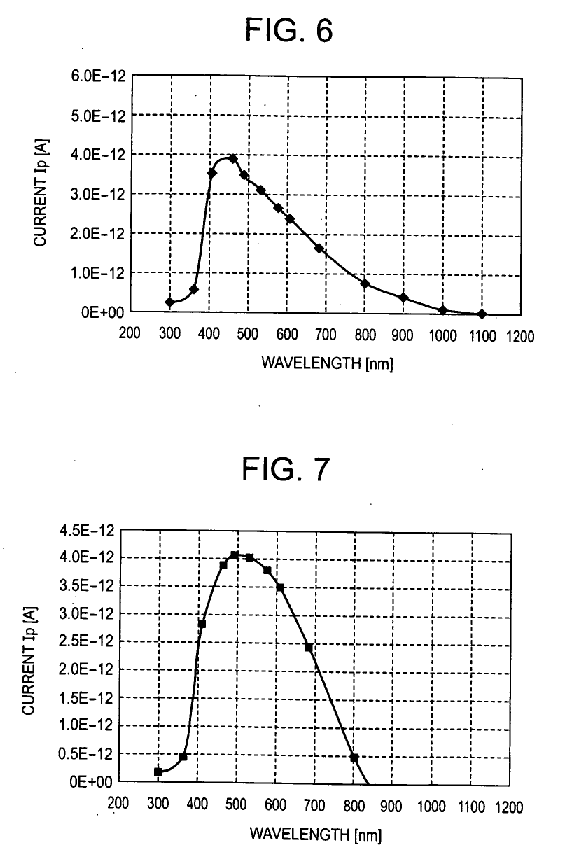

When the voltage is applied between the second P+ diffusion layer 33 and the second N+ diffusion layer 34 of the second visible light photosensitive element 31, a depletion layer shallow as viewed from the bottom face of the second P+ diffusion layer 33 is formed in the corresponding second N-well layer 32 formed shallow relatively. When light transmitted through the interlayer insulating film 52, NSG layer 62 and second P+ diffusion layer 33 is applied to the shallow depletion layer, light in a visible light region is mainly absorbed so that electron-positive hole pairs are generated, which in turn are pulled out as a current Ip-2 from the second P+ diffusion layer 33. When the voltage to be applied is assumed to be 1V and light having a wavelength ranging from 300 nm to 1100 nm is applied, a spectral sensitivity characteristic with a wavelength of 450 nm as a peak, which is shown in FIG. 6, is obtained.

The current Ip-2 of the second visible light photosensitive element 31 is multiplied by a predetermined coefficient and then subtracted from the current IP-1 of the first visible light photosensitive element 21, a spectral sensitivity characteristic shown in FIG. 7 with a wavelength of 500 nm as a peak, which mainly has sensitivity with respect to a wavelength ranging from 400 nm to 800 nm, is obtained, and the intensity of light in the visible light region is detected accurately.

The predetermined coefficient is set so as to cancel out spectral sensitivity of an infrared region of 800 nm or more at the current Ip-1 by the current Ip-2 through the subtraction.

The arithmetic operation, the application of the voltage and the like are carried out by the peripheral circuit comprised of the nMOS element 41 or the like formed in the silicon semiconductor layer 4.

Thus, since the photosensor 1 of the-present embodiment is one-chipped in a state in which it has the ultraviolet photosensitive element 11 formed in the silicon semiconductor layer 4 of the semiconductor substrate having the SOI structure, and the first and second visible light photosensitive elements 21 and 31 formed in the P-type silicon substrate 2, and has the function of detecting the ultraviolet light and the function of detecting the visible light, miniaturization of an apparatus equipped with the photosensor 1 can be easily attained.

Since one chipping is enabled inclusive of the peripheral circuit comprised of the nMOS element 41 or the like formed in the silicon semiconductor layer 4, the photo IC equipped with the photosensor 1 can be easily formed and hence the miniaturization of the apparatus equipped with the photosensor 1 can be further promoted.

In this case, the MOSFET for the nMOS element 41 or the like is formed in the silicon semiconductor layer 4 of the semiconductor substrate having the SOI structure because there are advantages that since no PN junctions are provided at the bottom faces of the source and drain layers 45 and 46 as compared with each MOSFET formed on a bulk substrate similar to the P-type silicon substrate 2, a high-speed operation is enabled as a result of suppression of parasitic capacitance, and since the MOSFET is completely separated from its adjacent semiconductor element by the element isolation layer 8 that reaches the embedded oxide film 3, malfunctions (latch-up or the like) in parasitic elements do not occur.

Further, in the present embodiment, the predetermined impurity is implanted in the silicon semiconductor layer 4 of the ultraviolet element forming area 5 and the P-type silicon substrate 2 for the first and second visible light element forming areas 10a and 10b after the formation of the element isolation layer 8, gate insulating film 42 and the like that require the heat treatment at the high temperature. Thereafter, the impurities in the respective implant layers are activated by once-heat treatment to form the diffusion layers. Therefore, impurity profiles for the respective implant layers can be easily controlled without the respective implant layers being affected by heat treatment in the course of the process.

Furthermore, in the ultraviolet photosensitive element 11 of the present embodiment, the predetermined impurity is diffused into the P-type high-concentration diffusion layer 12 and the N-type high-concentration diffusion layer 14 thereof. Thereafter, the silicon semiconductor layer 4 of the film-thinning area 7 is dug by etching to form the P-type low-concentration diffusion layer 15 thinned to the predetermined thickness. Therefore, even though surface roughening occurs in the upper surface of the P-type low-concentration diffusion layer 15 lying in the region adjacent to each high-concentration diffusion layer upon implantation of the high-concentration impurity ions for forming the P-type high-concentration diffusion layer 12 and the N-type high-concentration diffusion layer 14, each region in which surface roughening occurs subsequently can be removed, and the ultraviolet photosensitive element 11 reduced in dark current can be formed stably.

Still further, since the P-type high-concentration diffusion layer 12 and N-type high-concentration diffusion layer 14 of the ultraviolet photosensitive element 11 employed in the present embodiment are formed in the silicon semiconductor layer 4 having the same thickness as the silicon semiconductor layer 4 for forming the source and drain layers 45 and 46 of the nMOS element 41. Therefore, the depth of each contact hole that reaches the P-type high-concentration diffusion layer 12 and the N-type high-concentration diffusion layer 14 can be made identical to the depth of each contact hole that reaches the diffusion layers for the source layer 45 and the like of the nMOS element 41. The process used when the contact plugs are formed is simplified as compared with the case in which the thickness of the silicon semiconductor layer 4 for forming the nMOS element 41 and the like is set to another thickness, thereby making it possible to simplify the manufacturing process of the photosensor 1.

Still further, in the present embodiment, the insulating material layer (NSG layer 62) used for the mask or the like at the time that the silicide layer is formed, is formed using NSG corresponding to the same insulating material as the interlayer insulating film 52. Therefore, even if the thickness of the insulating material layer is increased to form the interlayer insulating film 52 in the state in which the insulating material layer used as the mask has been left, the influence of a refractive index at light penetration can be ignored. Further, the process of eliminating the insulating materials where the different insulating materials are used, is omitted, thereby making it possible to simplify the manufacturing process of the photosensor 1.

In the present embodiment as described above, the ultraviolet photosensitive element having the P-type low-concentration diffusion layer made thinner than the P-type high-concentration diffusion layer and the N-type high-concentration diffusion layer is formed in the silicon semiconductor layer lying on the embedded oxide film formed on the silicon substrate. The first visible light photosensitive element having the first N-well layer deep in depth as viewed from the light-detecting surface, and the second visible light photosensitive element having the second N-well layer shallow in depth are formed in the silicon substrate from which the element isolation layer and the embedded oxide film have been eliminated. Therefore, the photosensor equipped with the ultraviolet detecting function and the visible light detecting function can be one-chipped and thereby brought into less size, thus making it possible to facilitate miniaturization of an apparatus equipped with the photosensor.

Incidentally, although the above embodiment has described that the depths of the first N-well layer and the second N-well layer as viewed from the light-detecting surface are varied to change the depths of the depletion layers, the depths of the first N-well layer and the second N-well layer are made equal to each other and their impurity concentrations are made different from each other. The difference in concentration between the impurities for forming the PN junctions may be varied to change the depth of each depletion layer.

Although the above embodiment has described that the two visible light photosensitive elements are formed and the intensity of light in the visible light region is detected by the arithmetic operation, the number of the visible light photosensitive elements may be set to one using either of the first and second visible light photosensitive elements where each visible light photosensitive element is used under the environment less subject to infrared rays of a room or the like illuminated by a fluorescent light and where the accuracy is not so required, for example. If done in this way, then the manufacturing cost of the photosensor can be reduced and further miniaturization of the photosensor can be attained.

Further, although the above embodiment has described that the low-concentration diffusion layer of the ultraviolet photosensitive element is formed by diffusing the P-type impurity, an advantageous effect similar to the above can be obtained even if it is formed by diffusing the N-type impurity in a relatively low concentration.

Furthermore, although the above embodiment has described that the P-type high-concentration diffusion layer is “π”-shaped and the N-type high-concentration diffusion layer is “E”-shaped, their shapes may be set in reverse or the number of the comb-tooth portions may be further increased.

Still further, although the above embodiment has described that the first conductivity-type impurity diffused into each diffusion layer is of the P-type impurity and the second conductivity-type impurity is of the N-type impurity, an advantageous effect similar to the above can be obtained even if they are set in reverse, i.e., the N-type impurity is used as the first conductivity-type impurity and the P-type impurity is used as the second conductivity-type impurity.

While the preferred forms of the present invention have been described, it is to be understood that modifications will be apparent to those skilled in the art without departing from the spirit of the invention. The scope of the invention is to be determined solely by the following claims.

What is claimed is:

1. A photosensor formed in a semiconductor substrate having a silicon substrate, an insulating layer formed over the silicon substrate, and a silicon semiconductor layer formed over the insulating layer, comprising:
an ultraviolet photosensitive element formed in the silicon semiconductor layer; and
at least one visible light photosensitive element formed in the silicon substrate.

2. The photosensor according to claim 1, wherein the visible light photosensitive element is provided two, and
wherein the respective visible light photosensitive elements have visible light detection characteristics different from each other.

3. The photosensor according to claim 1, wherein a first diffusion layer having a first conductivity type, a second diffusion layer provided with being spaced away from the first diffusion layer and having a second conductivity type corresponding to a type opposite to the first conductivity type and a third diffusion layer which contacts the first diffusion layer and the second diffusion layer respectively and has the first conductivity type are formed in the silicon semiconductor layer of the ultraviolet photosensitive element.

4. The photosensor according to claim 3, wherein the thickness of the third diffusion layer of the ultraviolet photosensitive element is 3 nm or more and 36 nm or less.

5. A photo IC equipped with the photosensor according to claim 1, wherein MOSFETs for controlling the ultraviolet photosensitive element and the visible light photosensitive elements are formed in the silicon semiconductor layer.

6. The photo IC according to claim 5, wherein a first diffusion layer having a first conductivity type, a second diffusion layer provided with being spaced away from the first diffusion layer and having a second conductivity type corresponding to a type opposite to the first conductivity type and a third diffusion layer which contacts the first diffusion layer and the second diffusion layer respectively and has the first conductivity type are formed in the silicon semiconductor layer of the ultraviolet photosensitive element.

7. The photo IC according to claim 6, wherein the thickness of the third diffusion layer of the ultraviolet photosensitive element is 3 nm or more and 36 nm or less.

8. The photo IC according to claim 6, wherein the thickness of the silicon semiconductor layer of each of the MOSFETs is thicker than that of the third diffusion layer of the ultraviolet photosensitive element.

9. The photo IC according to claim 8, wherein the thickness of the silicon semiconductor layer of each of the MOSFETs is 40 nm or more and 100 nm or less.
